(19) United States
(12) Patent Application Publication
(10) Pub. No.: US 2009/0019328 A1
(43) Pub. Date: Jan. 15, 2009

(54) IC CIRCUIT WITH TEST ACCESS CONTROL CIRCUIT USING A JTAG INTERFACE

(75) Inventor: Leon Van De Logt, Son (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V.

(21) Appl. No.: 12/280,831

(22) PCT Filed: Feb. 21, 2007
(86) PCT No.: PCT/IB07/50558

§ 371 Date: Aug. 27, 2008

(30) Foreign Application Priority Data
Mar. 1, 2006 (EP) 06110569.8

(51) Int. Cl. G01R 31/3177; G06F 11/25

(52) U.S. Cl. 714/727; 714/E11.155

(57) ABSTRACT

An integrated circuit comprises a first circuit portion (106) with a JTAG interface (108) and a test access port (110). A second circuit portion (114) has a serial bus interface (112); and a test access control circuit (104) is connected to the JTAG interface (108) via the test access port (110). The first circuit portion (106) is connected to the serial bus interface (112) via the test access control circuit (104) and the test access control circuit (104) is programmable to be in a transparent mode or a test mode in response to a test mode select (TMS) signal from the JTAG interface (108). Thus, there is provided generic access to hidden serial bus interfaces while also maintaining speed performance such that the circuit portion/device under test can still be operated at device specification.

The present invention relates to the field of integrated circuits, and in particular to system in package (SIP) integrated circuits having internal circuitry with which it is desired to communicate via a serial bus interface.

In modern System-in-Package (SIP) Integrated Circuits (ICs) different combinations of chips are provided in one package to build a complete system. Communication between digital chip and mixed-signal/radio-frequency (RF) chips contained in such SIPs is conventionally achieved using one of the commonly known serial bus interfaces (SPI, 3-WIRE, uWIRE). It is also known to use this serial bus at chip level for controlling and debugging the specific mixed-signal/RF chip.

However, when such a serial bus is embedded within an SIP, the serial bus interface becomes inaccessible once the SIP is manufactured. As a result, system testing, debugging and characterization of the mixed-signal/RF part are all severely hampered.

To gain access and control over the different chips in the SIP, the access must be established again.

A known approach is to multiplex the inaccessible serial bus to other pins, but for different architectures the access may remain unobtainable because these pins are not connected to external package pins.

An alternative known approach is to provide a dedicated diagnostic circuit interface to the IC, for example a JTAG interface provided in accordance with IEEE Standard 1149.1. The JTAG standard states that the JTAG pins shall be available at the package of the IC, therefore accessibility to the JTAG interface is guaranteed for every SIP built to the JTAG standard.

Access through the JTAG interface is possible using the known method of Boundary Scan which is primarily used for testing ICs and synonymous with JTAG.

The boundary scan architecture of a JTAG interface provides a means to test interconnects without using physical test probes. When performing boundary scan inside integrated circuits, cells are added between logical design blocks in order to be able to control them as if they were independent circuits.

Such JTAG chains are also connected to the serial bus interface, and are typically long, for example 1000 cells. If this chain is used for data transfer to serial bus, the data must be shifted through 1000 cells (requiring 1000 clock cycles) before it reaches the serial interface. This introduces delays.

It is also known to provide a dedicated chain of a smaller number cells to the serial interface.

The known use of boundary scan thus does enable access for different SIP configurations, but there are speed and delay problems, and the known Boundary Scan method can also require complicated clocking systems.

Thus, it is desirable to provide for access to and control over an embedded serial bus while also enabling fully functional speed operation over the serial interface.

According to a first aspect of the invention there is provided an integrated circuit comprising: a first circuit portion having a JTAG interface and a test access port; a second circuit portion having a serial bus interface; and a test access control circuit connected to the JTAG interface via the test access port, wherein the first circuit portion is connected to the serial bus interface via the test access control circuit and the test access control circuit is programmable to be in a transparent mode or a test mode in response to a test mode select signal from the JTAG interface.

The test access control circuit enables the JTAG interface to be used for communication via the serial bus interface with the second circuit portion, which does not then need its own JTAG interface. The transparent mode also enables the normal circuit operation not to be compromised. In this way, testing of multiple circuit portions of a System-In-Package can be achieved using a JTAG interface of only one of the circuit portions.

The integrated circuit may be arranged such that: when the test access control circuit is in transparent mode, standard communication between the first circuit portion and the second portion via the serial bus interface is enabled; and when the test access control circuit is in test mode, communication through the JTAG interface to the serial bus interface via the test access port and test access control circuit is enabled.

The integrated circuit may be further arranged such that when the test access control circuit is in test mode, a Test Clock signal is used as a clock signal of the serial bus interface so that data transfer and communication is synchronized.

Thus, the invention provides generic and always available access to hidden serial interfaces while maintaining speed performance such that the circuit portion/device under test can still be operated at device specification (normal data communication). It also addresses the issue of synchronization for edge sensitive serial protocols.

Through the provision of a test access control circuit, normal (data) communication to the device is possible. In previous implementations either speed or access was limited or not implemented in a generic way. This invention overcomes both known issues.

The invention will find its application in the area of SIPs and for all other applications where access to the serial interface is limited but speed performance must be maintained.

According to a further aspect of the invention, there is provided a method of controlling a circuit comprising a first circuit portion having a JTAG interface and test access port, TAP, a second circuit portion having a serial bus interface, and a test access control circuit arranged such that it is connected to the JTAG interface via the TAP and the second circuit portion is connected to the serial bus interface via the test access control circuit, the method comprising the step of programming the test access control circuit is programmable to be in a transparent mode or a test mode in response to a Test Mode Select signal such that when the test access control circuit is in transparent mode, standard communication between the first circuit portion and the second portion via the serial bus interface is enabled; and when the test access control circuit is in test mode, communication through the JTAG interface to the serial bus interface via the TAP and test access control circuit is enabled.

An example of the invention will now be described in detail with reference to the accompanying drawings, in which:

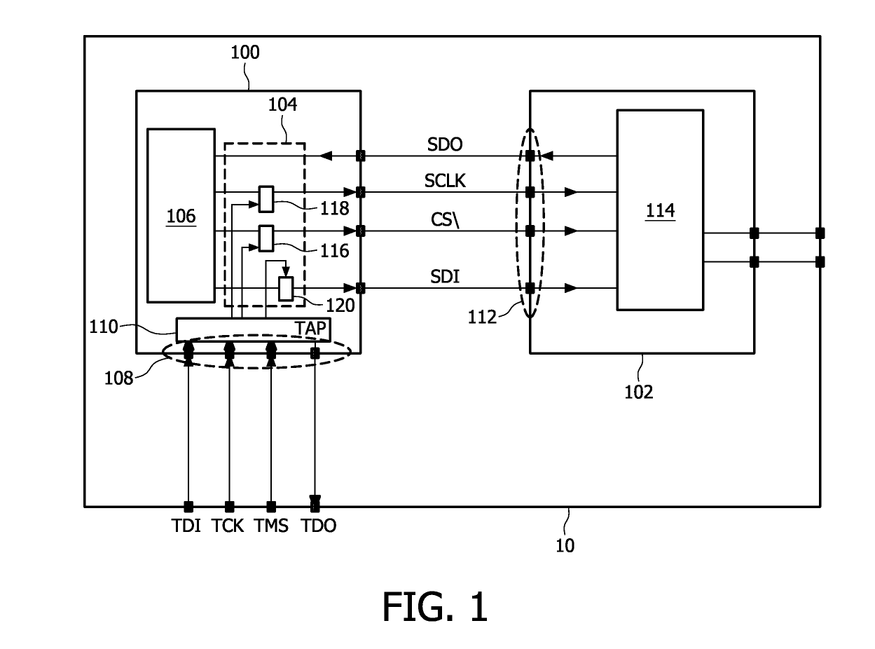

FIG. 1 shows a System-in-Package (SIP) containing an integrated circuit according to an embodiment of the invention;

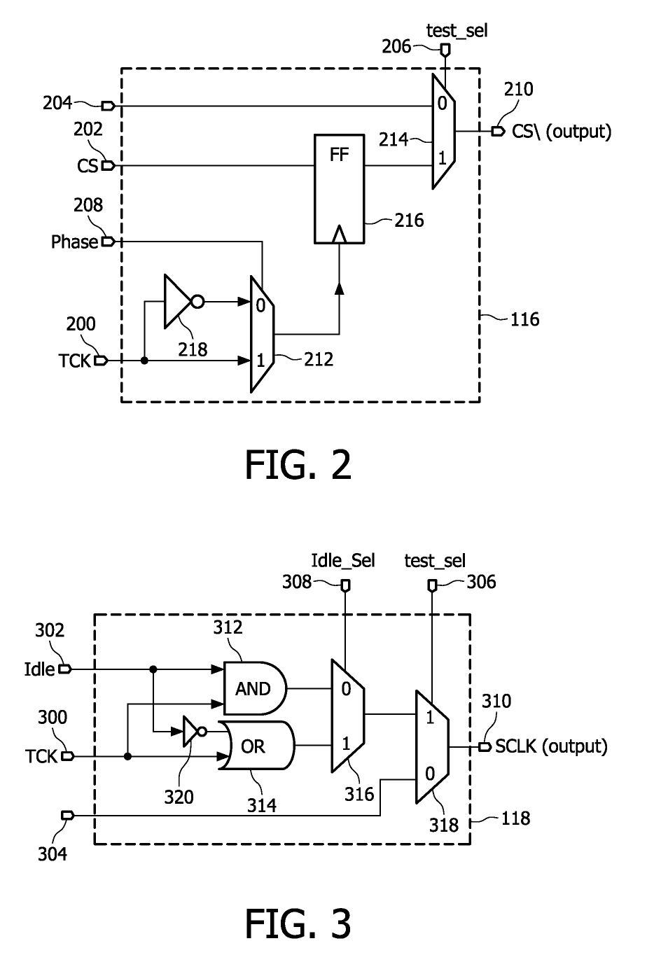

FIG. 2 shows the circuit cell for the chip select signal of the circuit of FIG. 1 in more detail;

FIG. 3 shows the circuit cell for the serial bus clock signal of the circuit of FIG. 1 in more detail;

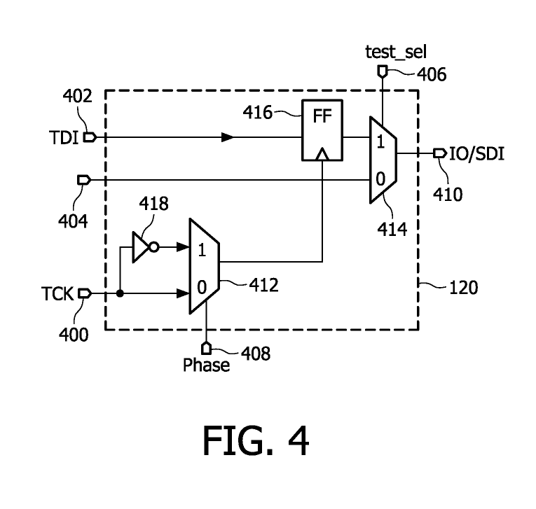

FIG. 4 shows the circuit cell for the serial data input signal of the circuit of FIG. 1 in more detail.

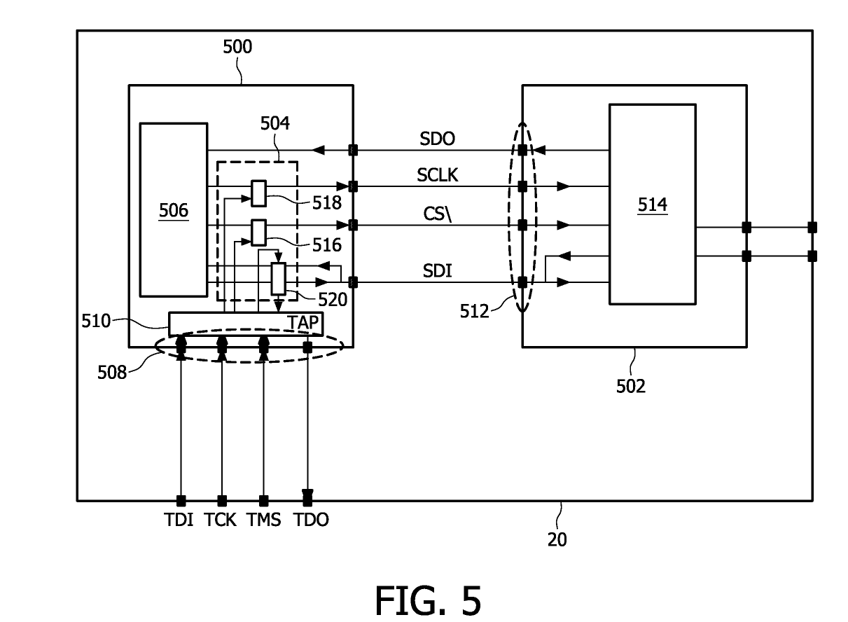

FIG. 5 shows a System-in-Package (SIP) containing an integrated circuit according to an alternative embodiment of the invention; and

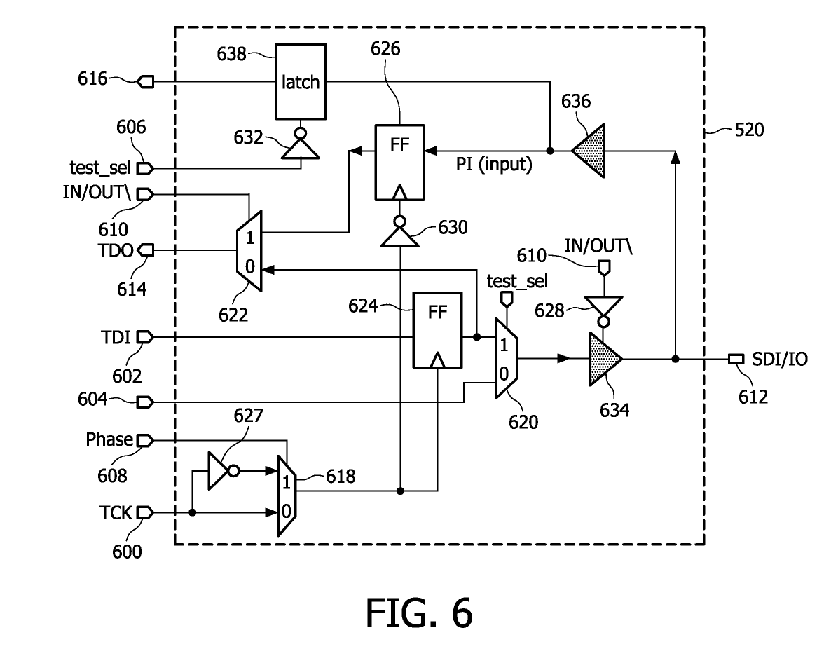

FIG. 6 shows the circuit cell for the serial data input/output signal of the circuit of FIG. 5 in more detail.

Referring to FIG. 1, an integrated circuit 10 comprises a first circuit section 100, a second circuit section 102, and a test access control (TAC) circuit 104. The test access control circuit is shown schematically as part of the first circuit section, but of course it may be a separate circuit.

The first circuit section 100 comprises digital core logic 106, a JTAG interface 108 and a test access port (TAP) 110. The JTAG interface 108 is a four/five-pin interface between the first circuit section 100 and the external pins of the integrated circuit 10 and is provided by every chip that supports the JTAG standard. According to the JTAG standard, the JTAG interface 108 supports the following dedicated signals: Test Data In (TDI); Test Data Out (TDO); Test Clock (TCK); Test Mode Select (TMS); and Test Reset (TRST).

“Test Reset” is an optional asynchronous reset signal and is not included in the JTAG interface 108 of FIG. 1. Although “Test Reset” is not shown in the embodiment of FIG. 1, the test logic can be reset by clocking in a reset instruction synchronously.

“Test Data In” supplies the serial data to the JTAG interface 108 and the data registers it is connected to. Since only one data line is available, the transmission protocol is necessarily serial.

“Test Data Out” is used to serially output the data from registers which are connected by the JTAG interface 108 to equipment controlling the test.

“Test Clock” controls the timing of the test interface independently from any system clocks. “Test Clock” is pulsed by the equipment controlling the test and not by the tested device. The operating frequency of “Test Clock” may vary depending on the circuit portion which the JTAG interface is used in, but is typically 10-100 MHz. It may even be pulsed at varying rates.

“Test Mode Select” controls the transitions of the test access port 110, the test access port 110 comprising a state controller (not shown) which is a state machine that controls the operations undertaken by the test.

The combination of the “Test Mode Select” and “Test Clock” signals determine the state in which the state controller is. The test access port 110 states are defined in instruction states and data states. The transition from one state to another is determined in accordance with IEEE1149.1. For the invention, the capture data state and shift data state are of relevance because synchronization and data shifting take place during these states. During test mode, the necessary control signals are assigned a value in one of these states.

The test access port 110 state machine is therefore the controlling mechanism for the synchronized data transfer to a serial bus. For example, during a data shift state, serial bus data is supplied to a serial bus register of the second circuit section 102 at each clock transition.

The second circuit section 102 comprises a serial bus interface 112 and mixed-signal/radio-frequency (RF) logic 114.

In the embodiment of FIG. 1, the communication protocol of the serial bus is Serial Peripheral Interface (SPI), a synchronous serial interface standard (defined by Motorola) using the following signals: Serial Data In (SDI); Serial Data Out (SDO); Chip Select (CS\); and Serial Clock (SCLK).

“Serial Data In” supplies serial data into a register of the serial bus and “Serial Data Out” supplies serial data out of a register of the serial bus. The timing of the serial bus communications is controlled by the “Serial Clock” signal, with the data being shifted/latched on the rising or falling edge of “Serial Clock” depending on the value of “Chip Select”. The “Chip Select” signal, therefore, controls the loading of the serial bus register. According to the Serial Peripheral Interface (SPI) protocol, when “Chip Select” is low, data is loaded into a serial bus register on each positive edge of the “Serial Clock” signal.

The test access control circuit 104 is arranged such that it is connected to the JTAG interface 108 via the test access port 110, and the digital core logic 106 is connected to the serial bus interface 112 via the test access control circuit 104.

The test access control circuit 104 is programmable to be in a transparent mode or a test mode in response to a “test_sel” signal provided by the test access port 110.

When “test_sel” has a value of digital low, ‘0’, the test access control circuit 104 is in a transparent mode and standard communication between the digital core logic 106 and the mixed-signal/radio-frequency (RF) logic 114 via the serial bus interface 112 is enabled.

When “test_sel” has a value of digital high, ‘1’, the test access control circuit 104 is in a test mode, and communication through the JTAG interface 108 to the serial bus interface 112 via the test access port 110 and test access control circuit 104 is enabled. During the test mode, the serial bus interface 112 is controlled using the test access port 110 state controller.

Thus, a transparent path from JTAG interface 108 to the serial bus interface 112 is provided. However, unlike a known approach of implementing a straightforward application of the JTAG interface, performance improvements are provided by the design of the test access control circuit 104.

The Serial Peripheral Interface (SPI) protocol states that when “Chip Select” is low the clock loads data on each positive edge of the “Serial Clock” signal. As a result, the known JTAG application of standard boundary scan chaining cannot be used without reducing speed performance.

In the present embodiment, the test access control circuit 104 is designed to keep the shift register as short as possible such that it corresponds with the normal shift action of the serial bus interface 112. In other words, this length cannot be more than one basic cell.

The test access control circuit 104 of the embodiment comprises a plurality of integrated circuit cells 116,118,120 which are arranged such that there is always only one cell connected between “Test Data In” and “Test Data Out” (i.e. every clock cycle a data bit is latched into the register of the serial bus). Each circuit cell has at least one input, at least one output, and a plurality of 2:1 multiplexers and the cells are controlled through dedicated JTAG control signals that can be made available from the test access port 110.

The test access control circuit 104 is also arranged such that when it is in test mode, the “Test Clock” signal is used as the clock signal of the serial bus, “Serial Clock”, such that data transfer and communication is synchronized.

As mentioned above, the test access control circuit 104 of the present embodiment comprises a plurality of integrated circuit cells 116,118,120. A first circuit cell 116 is arranged to supply to the “Chip Select” signal of the serial bus interface 112, a second circuit cell 118 is arranged to supply the “Serial Clock” signal to the serial bus interface 112, and a third circuit cell 120 is arranged to supply the “Serial Data In” signal to the serial bus interface 112. The specific arrangements of the integrated circuit cells 116,118,120 will now be described in more detail.

FIG. 2 shows the circuit cell 116 for the “Chip Select” signal of the circuit of FIG. 1 in more detail. The circuit cell 116 is arranged such that it has a first input terminal 200 connected to the “Test Clock” signal, a second input terminal 202 connected to a register loading signal (CS), a third input terminal 204 connected to the digital core logic 106, a fourth input terminal 206 connected to the “test_sel” signal, a fifth input terminal 208 connected to a positive/negative edge triggering signal (Phase), an output terminal 210 connected to the “Chip Select” signal of the serial bus interface 112, and control logic between the input and output terminals.

The positive/negative edge triggering signal (Phase) indicates the orientation of the edge triggering that is used by the serial bus interface 112.

When the potential of Phase is at a low level, negative edge triggering is used. Conversely, when the potential of Phase is at a high level, positive edge triggering is used.

The register loading signal (CS) indicates no register loading when it s high potential (1), whereas it indicates register loading when it is at low potential (0).

The control logic comprises first and second 2:1 multiplexers 212,214, a flip-flop 216 and an inverter 218.

The first 2:1 multiplexer 212 has its first and second signal terminals connected to the first input terminal 200, the first signal terminal being connected to the first input terminal 200 via the inverter 218. The selection terminal of the first multiplexer 212 is connected to the fifth input terminal 208. Accordingly, the first multiplexer 212 selects the complement of the “Test Clock” signal at the first input terminal 200 when a potential at the selection terminal of the first multiplexer 212 is at a low (0) level, and selects the “Test Clock” signal when the potential at the selection terminal of the first multiplexer 212 is at a high level (1).

The trigger of the flip-flop 216 is connected to the signal selected by the first multiplexer 212 and the input terminal of the flip-flop 216 is connected to the second input terminal 202. Thus, the flip-flop 216 drives the register loading signal (CS) signal applied to its input terminal to its output terminal on the positive edge of the signal selected by the first multiplexer 212 (either the positive or negative edge of “Test Clock”, depending on the value of the Phase signal).

The second 2:1 multiplexer 214 has its first signal and second signal terminals respectively connected to the third input terminal 204 and the output of the flip-flop 216. The selection terminal of the second multiplexer 214 is connected to the fourth input terminal 206. The second multiplexer 214, therefore, selects the signal from the digital core logic 106 when the potential of the “test_sel” signal at the selection terminal of the second multiplexer 214 is at a low (0) level, and selects the output from the flip-flop 216 when the potential of the “test_sel” signal at the selection terminal of the second multiplexer 214 is at a high level (1).

It can be appreciated that the “test_sel” signal selects between a transparent mode and a test mode. When the potential of “test_sel” is at a low level, the circuit cell 116 transparently connects the digital core logic 106 to the output terminal 210. However, when the potential of “test_sel” is at a high level, the digital core logic 106 is isolated from the output terminal 210 and the register loading signal is driven to the output terminal 210 depending upon the trigger signal applied to the flip-flop 216 (the positive edge of “Test Clock” if Phase=1, or the negative edge of “Test Clock” if Phase=0).

FIG. 3 shows the circuit cell 118 for the SCLK signal of the circuit of FIG. 1 in more detail. The second circuit cell 118 is arranged such that it has a first input terminal 300 connected to the “Test Clock” signal, a second input terminal 302 connected to a clock idle control signal (Idle), a third input terminal 304 connected to the digital core logic 106, a fourth input terminal 306 connected to the “test_sel” signal, a fifth input terminal 308 connected to an idle state control signal (Idle_Sel), an output terminal 310 connected to the “Serial Clock” signal of the serial bus interface 112, and control logic between the input and output terminals.

The idle state control signal (Idle_Sel), indicates the potential level of the clock when in an idle state (state of the clock before and after register loading). When the potential of Idle_Sel is at a low level, the idle state of the clock signal is a low potential (0). Conversely, when the potential of Idle_Sel is at a high level, the idle state of the clock signal is a high potential (1).

The control logic comprises a two-input AND logic gate 312, a two-input OR gate logic 314, first and second 2:1 multiplexers 316,318, and an inverter 320.

The first and second input terminals 300,302 of the circuit cell 118 are respectively connected to the first and second input terminals of the two-input AND logic gate 312. The AND gate 312 implements a logical AND of the “Test Clock” signal input applied to the first terminal 300 and the Idle signal applied to the second input terminal 302.

The AND gate 312 selectively passes or suppresses the “Test Clock” signal applied to the first input terminal 300 in response to the Idle signal applied to the second input terminal 302. The AND gate 312 outputs the “Test Clock” signal applied to the first input terminal 300 when the potential of the Idle signal applied to the second input terminal 302 is at a high (1) level, and outputs a low potential (0) signal when the Idle signal applied to the second input terminal 302 is at a low (0) level.

The first and second input terminals 300,302 of the circuit cell 118 are also respectively connected to the first and second input terminals of the two-input OR logic gate 314, the second input terminal being connected to an input terminal of the OR gate 314 via an inverter 320. The AND gate 312 implements a logical OR of the “Test Clock” signal input applied to the first terminal 300 and the Idle signal applied to the second input terminal 302.

The OR gate 314 selectively passes or suppresses the “Test Clock” signal applied to the first input terminal 300 in response to the Idle signal applied to the second input terminal 302. The OR gate 312 outputs the “Test Clock” signal applied to the first input terminal 300 when the potential of the Idle signal applied to the second input terminal 302 is at a high (1) level, and outputs a high potential (1) signal when the Idle signal applied to the second input terminal 302 is at a low (0) level.

The first 2:1 multiplexer 316 has its first and second signal terminals respectively connected to the output of the two-input AND logic gate 312 and the output of the two-input OR logic gate 314. The selection terminal of the first multiplexer 316 is connected to the fifth input terminal 308.

The first multiplexer 316 selects the output of the two-input AND logic gate 312 when a potential at the selection terminal of the first multiplexer 316 is at a low (0) level, and selects the output of the two-input OR logic gate 314 when the potential at the selection terminal of the first multiplexer 316 is at a high level (1).

The second 2:1 multiplexer 318 has its first and second signal terminals respectively connected to the third input terminal 304 and the output of the first 2:1 multiplexer 316. The selection terminal of the second multiplexer 318 is connected to the fourth input terminal 306. The second multiplexer 318 selects the signal from the digital core logic 106 when the potential at the selection terminal of the second multiplexer 318 is at a low (0) level, and selects the output from the first multiplexer 316 when the potential at the selection terminal of the second multiplexer 318 is at a high level (1).

It can therefore be appreciated that the “test_sel” signal selects between a transparent mode and a test mode for the second circuit cell 118. When the potential of “test_sel” is at a low level, the circuit cell 118 transparently connects the digital core logic 106 to the output terminal 310. However, when the potential of “test_sel” is at a high level, the digital core logic 106 is isolated from the output terminal 310 and the “Test Clock” signal is connected to the output terminal 310 depending upon the Idle_Sel and Idle signals. For example, during Test Mode (“test_sel”=1), if the potential of the Idle_Sel signal applied to the fifth input terminal 308 is at a low level (0) and the potential of the Idle signal applied to the second input terminal 302 is at a high level (1), the “Test Clock” signal is passed to the output terminal 310. Thus, the “Test Clock” signal can be selectively programmed to replace the SCLK signal of the serial bus interface 112.

FIG. 4 shows the circuit cell 120 for the SDI signal of the circuit of FIG. 1 in more detail.

The circuit cell 120 is arranged such that it has a first input terminal 400 connected to the “Test Clock” signal, a second input terminal 402 connected to a “Test Data In” signal, a third input terminal 404 connected to digital core logic 106, a fourth input terminal 406 connected to the “test_sel” signal, a fifth input terminal 408 connected to the positive/negative edge triggering signal (Phase), an output terminal 410 connected to the “Serial Data In” signal of the serial bus interface, and control logic between the input and output terminals.

The control logic comprises first and second 2:1 multiplexers 412,414, a flip-flop 416 and an inverter 418.

The first 2:1 multiplexer 412 has its first and second signal terminals connected to the first input terminal 400, the second signal terminal being connected to the first input terminal 400 via the inverter 418. The selection terminal of the first multiplexer 412 is connected to the fifth input terminal 408. Accordingly, the first multiplexer 412 selects the “Test Clock” signal at the first input terminal 400 when a potential at the selection terminal of the first multiplexer 412 is at a low (0) level, and selects the complement of the “Test Clock” signal when the potential at the selection terminal of the first multiplexer 412 is at a high level (1).

The trigger of the flip-flop 416 is connected to the signal selected by the first multiplexer 412 and the input terminal of the flip-flop 416 is connected to the second input terminal 402. Thus, the flip-flop 416 drives the “Test Data In” signal applied to its input terminal to its output terminal on the positive edge of the signal selected by the first multiplexer 412 (either the positive or negative edge of “Test Clock”, depending on the value of the Phase signal).

The second 2:1 multiplexer 414 has its first signal and second signal terminals respectively connected to the third input terminal 404 and the output of the flip-flop 416. The selection terminal of the second multiplexer 414 is connected to the fourth input terminal 406. The second multiplexer 414, therefore, selects the signal from the digital core logic 106 when the potential of the “test sel” signal at the selection terminal of the second multiplexer 414 is at a low (0) level, and selects the output from the flip-flop 416 when the potential of the “test_sel” signal at the selection terminal of the second multiplexer 414 is at a high level (1).

The “test_sel” signal selects between a transparent mode and a test mode for the third circuit cell 120. When the potential of “test_sel” is at a low level, the circuit cell 120 transparently connects the digital core logic 106 to the output terminal 410. However, when the potential of “test_sel” is at a high level, the digital core logic 106 is isolated from the output terminal 410 and the “Test Data In” signal is driven to the output terminal 410 depending upon the trigger signal applied to the flip-flop 216 (the negative edge of “Test Clock” if the potential of the Phase signal is high (1), or the positive edge of “Test Clock” if the potential of the Phase signal is low (0)).

It is noted that the trigger signal arrangement for the third circuit cell 120 is opposite to that of the first circuit cell 116. Thus, when the Serial Peripheral Interface (SPI) protocol is adhered to (when the potential of “Chip Select” is low, data is loaded into a serial bus register on each positive edge of the clock signal and, thus, the potential of the Phase signal is high), the data is driven to the “Serial Data In” signal of the serial bus at the negative edge of the clock signal and loaded into the register of the serial bus at the next positive edge of the clock signal (½ clock cycle delay).

There are however, variations to the protocol. In some cases register loading occurs while “Chip Select” is high and the clock edge sensitivity can be positive or negative. Additionally, the clock idle state can be either high or low. The differences depend on the implementation chosen by the manufacturer. The newly developed cells therefore cater for these differences.

Operation of the circuit cells 116,118,120 for data communication under the standard Serial Peripheral Interface (SPI) protocol (positive edge clocking and register loading when CS\=0) while the test mode is enabled will now be described in further detail.

When test mode is enabled, the potential of the “test_sel” signal is high (1) and, as described above, the circuit cells 116,118,120 isolate the digital core logic 106 from their output terminals and the serial bus interface 112.

The potential of the Phase signal is set to high level (1) to arrange for a positive edge sensitive serial bus interface and the potential of the idle_sel signal is set to low (0) to indicate the clock idle state is low.

Prior to any data transfer, the potential of the CS signal is set to high (1) to indicate no register loading and the potential of idle is low (0).

To commence data communication, the potential of the CS signal is set to low (0) just before shifting of data is started and a ‘capture’ state (CDR) is entered.

As described above, the flip-flop 216 in the first circuit cell 116 drives the low value of the CS signal to the output 210 of the first circuit cell 116 at the positive edge of “Test Clock”.

In the same state (CDR), the potential of the idle signal is set to high (1) and, as described above, the “Test Clock” signal at the first input terminal 300 of the second circuit cell 118 is provided to the output terminal of the second circuit cell 118. Thus, the “Test Clock” signal becomes the SCLK signal of the serial bus interface 112.

At the next negative edge of “Test Clock” signal, the flip-flop 416 in the third circuit 120 drives a first data bit of the “Test Data In” signal to the output 410 of the third circuit cell 120 (as described above). It is noted that the flip-flop 416 in the third circuit cell 120 is negative edge sensitive (while the flip-flop 214 of the first circuit cell 116 is positive edge sensitive) for a positive edge sensitive serial bus interface 112.

Upon completion of data capture state (CDR), the protocol is ready for shifting and clocking data during a shift state (SDR). At the next first positive edge of the “Test Clock” signal the first data bit will be loaded into a register of the serial bus interface.

This demonstrates that data transfer and synchronization is in the functional domain (transparent) for the second circuit section 102. In other words, the logic 114 of the second circuit section 102 reacts as if it is a normal serial bus interface operation.

This process of data capture and shifting continues until all data bits are loaded into the register. When the process has been completed, the potential of the idle signal is set to low in an exit state (E1D). Data transmission is then complete.

Although the embodiment of the invention has been described as using the Serial Peripheral Interface (SPI) communication protocol, the embodiment may also be implemented for use with the uWIRE communication protocol which is the predecessor of SPI (using the same signals and timing, but with variations in signal polarity as mentioned above).

Referring to FIG. 5, a System-in-Package (SIP) containing an integrated circuit according to an alternative embodiment of the invention is shown.

The integrated circuit comprises a first circuit portion 500, a second circuit portion 502, and a test access control circuit (TAC) 504.

The first circuit section 500 comprises digital core logic 506, a JTAG interface 508 and test access port (TAP) 510.

The second circuit section 502 comprises a serial bus interface 512 and mixed-signal/radio-frequency (RF) logic 514.

In the present embodiment of FIG. 5, the communication protocol of the serial bus interface 512 is 3-WIRE, a synchronous serial interface standard (defined by Maxim) using the same signals and timing as the Serial Peripheral Interface (SPI) protocol. However, the 3-WIRE protocol uses a single I/O data pin for data transfer (unlike SPI which uses separate data input and data output lines). Thus, in the embodiment of FIG. 5, an I/O pin is catered for through the combination “Serial Data In” and “Serial Data Out” signals on the same serial bus interface pin.

The test access control circuit 504 is arranged such that it is connected to the JTAG interface 508 via the test access port 510 and the first circuit section 500 is connected to the serial bus interface 512 via the test access control circuit 504.

The test access control circuit 504 is programmable to be in a transparent mode or a test mode in response to the “test_sel” signal (as described above for the embodiment of FIG. 1). Thus, a transparent path from JTAG interface 508 to the serial bus interface 512 is provided.

In the embodiment, the test access control circuit 504 is designed to keep the shift register as short as possible such that it corresponds with the normal shift action of the serial bus interface 512. In other words, this length cannot be more than one basic cell.

The test access control circuit 504 of the present embodiment comprises a plurality of integrated circuit cells 516,518,520 which are arranged such that there is always only one cell connected between “Test Data In” and “Test Data Out” (i.e. every clock cycle a data bit is latched into the register of the serial bus). Each circuit cell has at least one input, at least one output, and a plurality of 2:1 multiplexers and the cells are controlled through dedicated JTAG interface 508 control signals that can be made available from the test access port 510.

The test access control circuit 504 is also arranged such that when it is in test mode, the “Test Clock” signal is used as a clock signal of the serial bus, “Serial Clock”, such that data transfer and communication is synchronized.

As mentioned above, the test access control circuit 504 of the present embodiment comprises a plurality of integrated circuit cells 516,518,520. A first circuit cell 516 is arranged to supply the “Chip Select” signal to the serial bus interface 512, a second circuit cell 518 is arranged to supply the “Serial Clock” signal to the serial bus interface 512, and a third circuit cell 520 is arranged to supply a bidirectional “Serial Data In/Out” (SDI/IO) signal to the serial bus interface 512.

The first and second circuit cells 516,518 of the present embodiment are identical to the first and second circuit cells 116,118 of the embodiment shown in FIG. 1. Thus, they have been described in more detail within the above description and in FIGS. 2 and 3 respectively.

The specific arrangements of the third integrated circuit cell 520 will now be described in more detail with reference to FIG. 6.

The third circuit cell 520 is arranged such that it has a first input terminal 600 connected to the “Test Clock” signal, a second input terminal 602 connected to the “Test Data In” signal, a third input terminal 604 connected to the first circuit section 500, a fourth input terminal 606 connected to the “Test Mode Select” signal, a fifth input terminal 608 connected to the positive/negative edge triggering signal (Phase), a sixth input terminal 610 connected to a data direction control signal (IN/OUT\), a first bidirectional input/output terminal 612 connected to the “Serial Data In/Out” (SDI/IO) signal of the serial bus interface 512, a second output terminal 614 connected to the “Test Data Out” signal, a third output terminal 616 connected to the first circuit portion 500, and control logic between the input and output terminals.

The control logic comprises first to third 2:1 multiplexers 618,620,622, first and second flip-flops 624,626, first to fourth inverters 627,628,630,632, first and second buffers 634,636 and a data latch 638.

The first 2:1 multiplexer 618 has its first and second signal terminals connected to the first input terminal 600, the second signal terminal being connected to the first input terminal 600 via the first inverter 627. The selection terminal of the first multiplexer 618 is connected to the fifth input terminal 608. Accordingly, the first multiplexer 618 selects the “Test Clock” signal at the first input terminal 600 when a potential at the selection terminal of the first multiplexer 618 is at a low (0) level, and selects the complement of the “Test Clock” signal when the potential at the selection terminal of the first multiplexer 618 is at a high level (1).

The trigger of the first flip-flop 624 is connected to the signal selected by the first multiplexer 618 and the input terminal of the first flip-flop 624 is connected to the second input terminal 602. Thus, the first flip-flop 624 drives the “Test Data In” signal applied to its input terminal to its output terminal on the positive edge of the signal selected by the first multiplexer 618 (either the positive or negative edge of “Test Clock”, depending on the value of the Phase signal).

The second 2:1 multiplexer 620 has its first signal and second signal terminals respectively connected to the third input terminal 604 and the output of the first flip-flop 624. The selection terminal of the second multiplexer 620 is connected to the fourth input terminal 606. The second multiplexer 620, therefore, selects the signal from the first circuit portion 500 when the potential of the “test_sel” signal at the selection terminal of the second multiplexer 620 is at a low (0) level, and selects the output from the first flip-flop 624 when the potential of the “test_sel” signal at the selection terminal of the second multiplexer 620 is at a high level (1).

The output signal terminal of the second multiplexer 620 is connected to the bidirectional input/output terminal 612 via the first buffer 634, the enable pin of the first buffer 634 being connected to the sixth input terminal 610 via the second inverter 628.

Thus, the “test_sel” signal selects between a transparent mode and a test mode for the third circuit cell 520. When the potential of “test_sel” is at a low level, the circuit cell 520 transparently connects the digital core logic 106 to the bidirectional input/output terminal 612. However, when the potential of “test_sel” is at a high level, the first circuit section 500 is isolated from the bidirectional input/output terminal 612 and the “Test Data In” signal is driven to the input/output terminal 612 depending upon the trigger signal applied to the first flip-flop 624 (the negative edge of “Test Clock” if the potential of the Phase signal is high (1), or the positive edge of “Test Clock” if the potential of the Phase signal is low (0)) and the IN/OUT\ signal applied to the first buffer 634.

The data direction control signal (IN/OUT\) controls the direction of the bidirectional input/output terminal 612 and is set at the beginning of the protocol. If the potential of the data direction control signal (IN/OUT\) is at a low level (0), the first buffer 634 is enabled and the signal selected by the second multiplexer 620 is passed the bidirectional terminal 612 as an output signal. If the potential of the IN/OUT\ signal is at a high level (1), the first buffer 634 is disabled and bidirectional terminal 612 provides for the input of a signal.

The bidirectional terminal 612 is connected to the input terminal of the second flip-flop 626 via the second buffer 636, and the trigger of the second flip-flop 626 is connected to the signal selected by the first multiplexer 618 via the third inverter 630. Thus, the second first flip-flop 626 drives an input signal applied to the bidirectional terminal 612 to its output terminal on the positive edge of the signal selected by the first multiplexer 618.

The bidirectional terminal 612 is also connected to the input terminal of the data latch 638 via the second buffer 636, and the enable input of the data latch 638 is connected to the fourth input terminal 606 via the fourth inverter 632. The output terminal of the data latch 638 is connected to the third output terminal 616. Thus, the latch 638 stores and outputs data applied to the bidirectional terminal 612 according to the “test_sel” signal.

The third 2:1 multiplexer 622 has its first signal and second signal terminals respectively connected to the output of the first flop-flop 624 and the output of the second flip-flop 626 respectively. The selection terminal of the third multiplexer 622 is connected to the sixth input terminal 6 10. The third multiplexer 622, therefore, selects the “Test Data In” signal when the potential of the “test_sel” signal at the selection terminal of the third multiplexer 622 is at a low (0) level, and selects the signal output from the second flip-flop 626 (an input signal applied to the bidirectional terminal 612) when the potential of the “test_sel” signal at the selection terminal of the third multiplexer 622 is at a high level (1).

The second output terminal 614 is connected to the signal selected by the third multiplexer 622, which therefore provides the “Test Data Out” signal.

If the potential of the IN/OUT\ signal is at a low level (0), the “Test Data In” signal output from the first flip-flop 624 is selected by the third multiplexer 622 and output by the second output terminal 614 as the “Test Data Out” signal. Alternatively, if the potential of the IN/OUT\ signal is at a high level (1), the signal output by the second first flip-flop 626 (an input signal applied to the bidirectional terminal 612) is selected by the third multiplexer 622 and output by the second output terminal 614 as the “Test Data Out” signal. Thus, the third multiplexer 622 enables reading back the shifted data to “Test Data Out” for further processing.

It is noted that the third multiplexer 622 may be absent in alternative embodiments of the invention since the provision for reading back the shifted data may be an optional feature.

It is noted that the second flip-flop 626 for reading input data from the bidirectional terminal 612 is triggered on an opposite polarity to that of the first flip-flop 624 for compliance with the protocol timings as described in the previous embodiment of the invention. The data is driven to the “Serial Data In/Out” (SDI/IO) signal of the serial bus interface at the negative edge of the clock signal and loaded/read from the “Serial Data In/Out” (SDI/IO) signal of the serial bus at the next positive edge of the clock signal (½ clock cycle delay).

The invention uses a JTAG interface for at-speed (transparent) communication to an internally hidden serial bus whilst also being in a test mode and undertaking communication independent of the digital chip. Further, the JTAG interface enables data transfer and synchronization through test access control circuit.

Various other modifications will be apparent to those skilled in the art.

1. An integrated circuit comprising:
a first circuit portion (106) having a JTAG interface (108) and a test access port (110);
a second circuit portion (114) having a serial bus interface (112); and
a test access control circuit (104) connected to the JTAG interface (108) via the test access port (110), wherein
the first circuit portion (106) is connected to the serial bus interface (112) via the test access control circuit (104) and the test access control circuit (104) is programmable to be in a transparent mode or a test mode in response to a test mode select (TMS) signal from the JTAG interface (108).

2. An integrated circuit as claimed in claim 1 wherein:
when the test access control circuit (104) is in transparent mode, standard communication between the first circuit portion (106) and the second portion (114) via the serial bus interface (112) is enabled; and
when the test access control circuit (104) is in test mode, communication through the JTAG interface (108) to the serial bus interface (112) via the test access port (110) and test access control circuit (104) is enabled.

3. An integrated circuit as claimed in claim 2 wherein when the test access control circuit (104) is in test mode, a Test Clock signal is used as a clock signal of the serial bus interface (112), such that data transfer and communication is synchronized.

4. An integrated circuit as claimed in claim 1, wherein the test access control circuit (104) comprises a plurality of integrated circuit cells (116,118,120), each circuit cell having at least one input, at least one output, and a plurality of 2:1 multiplexers.

5. An integrated circuit as claimed in claim 4 wherein:
a first circuit cell (116) is arranged such that it has a first input (200) connected to a Test Clock signal (TCK), a second input (202) connected to a register loading signal (CS), a third input (204) connected to the first circuit portion (106), a fourth input (206) connected to the Test Mode Select signal (TMS), a fifth input (208) connected to a positive/negative edge triggering signal (Phase), and a first output (210) connected to a chip select signal (CS\) of the serial bus interface (112);
a second circuit cell (118) is arranged such that it has a first input (300) connected to the Test Clock (TCK) signal, a second input (302) connected to a clock idle control signal (Idle), a third input (304) connected to the first circuit portion (106), a fourth input (306) connected to the Test Mode Select signal (TMS), a fifth input (308) connected to an idle state control signal (Idle_Sel), and a first output (310) connected to a clock signal (SCLK) of the serial bus interface (112);
a third circuit (120) is arranged such that it has a first input (400) connected to the Test Clock signal (TCK), a second input (402) connected to a Test Data In signal (TDI), a third input (404) connected to the first circuit portion (106), a fourth input (406) connected to the test selection signal (test_sel), a fifth input (408) connected to a positive/negative edge triggering signal (Phase), and a first output (410) connected to a data input signal (SDI) of the serial bus interface (112).

6. An integrated circuit as claimed in claim 5 wherein the data input signal of the serial bus interface (512) is a bi-directional signal (SDI/IO), and the third circuit cell (520) is further arranged such that is has a sixth input (610) connected to a pin direction control signal (IN/OUT\), a second output (614) connected to a Test Data Out signal (TDO), a third output (616) connected to the first circuit portion (106) and the first output is a bidirectional input/output (612) connected to a bi-directional data signal (SDI/IO) of the serial bus interface (512),

7. An integrated circuit as claimed in claim 5, wherein:
the first circuit cell (116) comprises first and second 2:1 multiplexers (212,214), a flip-flop (216) and an inverter (218);
the second circuit cell (118) comprises first and second 2:1 multiplexers (316,318), a two-input logic AND gate (312), a two-input logic OR gate (314), and an inverter (320); and
the third circuit cell (120) comprises first and second 2:1 multiplexers (412,414), a flip-flop (416) and an inverter (418).

8. An integrated circuit as claimed in claim 7, wherein:
the third circuit cell further comprises a third 2:1 multiplexer (622), a second flip-flop (626), a data latch (638), second to fourth inverters (628,630,632) and first and second buffers (634,636).

9. A method of controlling a circuit comprising a first circuit portion (106) having a JTAG interface (108) and test access port (110), a second circuit portion (114) having a serial bus interface (112), and a test access control circuit (104) arranged such that it is connected to the JTAG interface (108) via the test access port and the second circuit portion is connected to the serial bus interface via the test access control circuit, the method comprising the step of
programming the test access control circuit is programmable to be in a transparent mode or a test mode in response to a test selection signal such that:
when the test access control circuit is in transparent mode, standard communication between the first circuit portion and the second portion via the serial bus interface is enabled; and
when the test access control circuit is in test mode, communication through the JTAG interface to the serial bus interface via the test access port and test access control circuit is enabled.
